(19) United States
(12) Patent Application Publication
(10) Pub. No.: US 2009/0311947 A1
(43) Pub. Date: Dec. 17, 2009

(54) Polishing Composition for Silicon Wafer and Polishing Method of Silicon Wafer

(75) Inventors: Naoyuki Iwata, Tokyo (JP); Isao Nagashima, Tochigi (JP)

Correspondence Address: Workman Nydegger;1000 Eagle Gate Tower, 60 East South Temple, Salt Lake City, UT, 84111, US

(73) Assignee: Dupont AurProducts NanoMaterials Limited Company, Tempe, AZ (US)

(21) Appl. No.: 12/307,056

(22) PCT Filed: Oct. 18, 2006
(86) PCT No.: PCT/JP2006/320758

§ 371 Date: Aug. 3, 2009

(30) Foreign Application Priority Data
Jul. 5, 2006 (JP) 2006-185974

(51) Int. Cl. B24B 37/04; C09K 3/14; H01L 21/304

(52) U.S. Cl. 451/41; 51/309

(57) ABSTRACT

The present invention provides a polishing composition used in a polishing process of a silicon wafer, which has an improved smoothness and is environment-friendly. The polishing composition for the silicon wafer of the present invention comprises a metal oxide, an alkaline substance and water, wherein the alkaline substance is guanidines. Another polishing composition for a silicon wafer of the present invention comprises an alkaline substance and water, wherein the alkaline substance is guanidines. These polishing compositions may further comprise a chelating agent. The metal oxide is preferably a cerium oxide or a silicon oxide. The present invention encompasses a polishing method using the above polishing composition and a kit for the above polishing composition.

### TECHNICAL FIELD

This invention relates to a polishing composition for a silicon wafer and a polishing method of the silicon wafer.

### BACKGROUND ART

A polishing process of a silicon wafer generally comprises a primary polishing process, a secondary polishing process and a final polishing process. In a polishing process of a semiconductor wafer, particularly a silicon wafer, various kinds of alkaline substances are used for improving a polishing speed (for example, refer to Japanese Patent Publication No. 61-38954 (Patent Document 1), Japanese Patent No. 3440419 (Patent Document 2)). As the alkaline substances, for example, there are used an inorganic alkaline substance such as sodium hydroxide, potassium hydroxide, sodium carbonate and potassium carbonate; amines such as piperazine, 2-aminoehtanol and ethylene diamine; or tetramethylammonium hydroxide. These alkaline substances are conventionally contained in the polishing compositions mainly of the primary polishing process and/or the secondary polishing process in the polishing process of the silicon wafer.

It is considered that among the above alkaline substances, the amines bring about metal contamination during the polishing. Some amines are proscribed under the Act on Confirmation, etc. of Release Amounts of Specific Chemical Substances in the Environment and Promotion of Improvements to the Management Thereof (Pollutant Release and Transfer Register (PRTR)). The sodium hydroxide or the potassium hydroxide possibly has a low polish promotion capability, and the sodium carbonate or the potassium carbonate may bring about aggregation of silica formulated in a conventional polishing composition.

In addition to the aforementioned problems of the alkaline substance, there exist many kinds of capabilities required in the polishing composition for the silicon wafer. Among others, due to high integration of a silicon device at present, there is an increasing demand for high smoothness of a polished silicon wafer. Since large amounts of polishing compositions are used, there is required also an increasing consideration to an environment in a case of disposing the used polishing compositions. Accordingly, in a case of using alkaline substances, use of chemicals prescribed under PRTR law should be avoided as much as possible.

Patent Document 1: Japanese Patent Publication No. 61-38954
Patent Document 2: Japanese Patent No. 3440419

### DISCLOSURE OF THE INVENTION

The present invention has an object of providing a polishing composition used in a polishing process of a semiconductor wafer, particularly a silicon wafer, which has an improved smoothness and is environment-friendly. The present invention has an object of providing a polishing method of a silicon wafer using this polishing composition.

The present invention is made in view of the above-mentioned problems and relates to a polishing composition which improves smoothness and is environment-friendly without using conventional amines as an alkaline substance.

The present invention relates to a polishing composition for a silicon wafer comprising a metal oxide, an alkaline substance and water, wherein the alkaline substance is guanidines. The present invention further relates to a polishing composition for a silicon wafer comprising an alkaline substance and water, wherein the alkaline substance is guanidines.

The polishing composition of the present invention may include a chelating agent. It is preferable that the guanidines are selected from guanidine, guanidine carbonate, guanidine hydrochloride, aminoguanidine, aminoguanidine carbonate, aminoguanidine hydrochloride, biguanide, biguanide carbonate, biguanide hydrochloride, or sulfamic acid salt of guanidine. In the case of guanidine hydrochloride, another alkaline substance may be together used for increasing pH. The chelating agent is preferably selected from ethylene diamine tetraacetic acid, diethylenetriamine pentaacetic acid, nitrilotriacetic acid, N-hydroxyethylethylene diaminetriacetic acid, or hydroxyethyliminodiacetic acid. The metal oxide is preferably selected from cerium oxide or silicon oxide. It is preferable that the polishing composition has pH of 10.2 to 12.0.

The present invention comprises a polishing method of a silicon wafer. A first polishing method of the present invention comprises polishing a silicon wafer with colloidal ceria comprising a cerium oxide and water or colloidal silica comprising a silicon oxide and water, and with a polishing composition for a silicon wafer comprising an alkaline substance and water, wherein the alkaline substance is guanidines.

A second polishing method is a polishing method of a silicon wafer comprising removing an oxidized layer on a silicon wafer surface by polishing the silicon wafer surface with colloidal ceria comprising cerium oxide and water, and subsequently polishing a silicon wafer with an alkaline polishing composition comprising an alkaline substance and water, wherein the alkaline substance is guanidines.

According to the polishing method of the present invention, the polishing composition may comprise a chelating agent and the chelating agent is preferably the materials as described above. Further, the guanidines are preferably the materials as described above.

The present invention comprises a semiconductor wafer polishing composition kit. A first kit of the present invention may comprise colloidal ceria comprising a cerium oxide and water or colloidal silica comprising a silicon oxide and water, and an alkaline polishing composition comprising an alkaline substance and water (hereinafter, referred to also as dispersion liquid). A second kit of the present invention may comprise an alkaline polishing composition comprising an alkaline substance and water.

According to the present invention, at least one of the colloidal ceria or the colloidal silica and the alkaline polishing composition of the first kit may comprise a chelating agent. The alkaline polishing composition of the second kit may comprise the chelating agent. In the kit of the present invention, the alkaline substance is guanidines. The chelating agent and the guanidines of the present invention are preferably the materials as described above.

The polishing composition and the polishing composition kit of the present invention may be diluted before the polishing. According to the polishing composition in the present invention, high smoothness can be realized in high effectiveness. An application of PRTR law is not made to the above guanidines.

### DETAIL DESCRIPTION OF THE INVENTION

The present invention relates to a polishing composition for a semiconductor wafer, and particularly to a polishing composition for a silicon wafer. A first polishing composition for a silicon wafer of the present invention comprises a dispersion liquid comprising a metal oxide and water and an alkaline polishing composition comprising an alkaline substance and water. A second polishing composition for a silicon wafer of the present invention comprises an alkaline polishing composition comprising an alkaline substance and water.

In the polishing composition of the present invention, the alkaline substance comprises guanidines. Use of the guanidines can provide a polishing composition which has an improved smoothness on the silicon wafer and is environment-friendly.

It is preferable that the metal oxide is selected from cerium oxide or silicon oxide. In the present invention, the cerium oxide is used as colloidal ceria in which the powder of the cerium oxide is dispersed in water. The silicon oxide may be used in such a manner as to disperse the powder thereof in water or may use a silica sol made from sodium silicate. In the present specification, a dispersion in which the cerium oxide powder is dispersed in water is called colloidal ceria and a dispersion in which the silicon oxide powder is dispersed in water or the silica sol made from the sodium silicate is called colloidal silica. A dispersion in which powder of a metal oxide is dispersed in water is called a dispersed liquid (in the present invention, particularly, a generic name of colloidal ceria or colloidal silica). Further, in the present specification, a solution or a dispersion in which the alkaline substance is dissolved or dispersed in water is called an alkaline polishing composition.

In the present invention, the first and the second polishing compositions for the silicon wafer may further comprise a chelating agent. The chelating agent is a material for preventing contamination of a semiconductor wafer due to a metal. By use of the chelating agent, metallic ions existing in the polishing composition react to the chelating agent to form complex ions, thereby efficiently preventing the metal contamination on a silicon wafer surface.

The present invention relates to a polishing composition generally used in a primary polishing process and/or a secondary polishing process of a semiconductor wafer.

The second polishing composition of the present invention comprises only an alkaline polishing composition comprising an alkaline substance and water. Such polishing composition can not carry out effective polishing in a case where an oxidized layer (natural oxidized layer) is on a silicon wafer at the time of polishing the silicon wafer. In a case where the oxidized layer is formed on the silicon wafer, after removing this layer, the polishing of the silicon wafer is carried out by the second polishing composition of the present invention. The removal of the oxidized layer on the silicon wafer may be carried out by polishing the silicon wafer with colloidal ceria or colloidal silica, for example.

An explanation of the respective materials and a preparation method of the polishing composition will be explained below.

<Each Component of Polishing Composition>

(1) Metal Oxide

(1-1) Colloidal Ceria

In the polishing composition of the present invention, colloidal ceria comprising cerium oxide powder and water is used. The colloidal ceria may be prepared by dispersing the cerium oxide in the water, or the colloidal ceria in which the cerium oxide is in advance blended with the water may be purchased for use. The colloidal ceria can be obtained from Nyacol Co, for example. An amount of the cerium oxide contained in the polishing composition is, for example, in the polishing of the silicon wafer, in a range of 2.5 ppm to 100 ppm (0.0025 to 1 parts by weight relative to 1000 parts by weight of a polishing composition) in a diluted state as used at an actual polishing work time (hereinafter, referred to also as use point of polishing), preferably 2.5 ppm to 250 ppm (0.0025 to 0.25 parts by weight relative to 1000 parts by weight of a polishing composition). When the amount is less than 2.5 ppm, the polishing does not substantially advance. When the amount exceeds 100 ppm, the polishing is carried out substantially efficiently, but an economical efficiency deteriorates.

(1-2) Colloidal Silica

In the polishing composition of the present invention, colloidal silica comprising silicon oxide powder and water may be used or silica sol made from sodium silicate may be used. The colloidal silica can be obtained from DuPont Air Products NanoMaterials Co. (DANM CO), for example. An amount of the silicon oxide contained in the polishing composition is, for example, in the polishing of the silicon wafer, in a range of 0.05% to 5% at a use point. When the amount is less than 0.05%, the polishing does not substantially advance. When the amount exceeds 5%, the polishing is carried out substantially efficiently, but an economical efficiency deteriorates.

(2) Alkaline Substance

In the polishing composition of the present invention, guanidines are used as an alkaline substance. The guanidines is selected from guanidine, guanidine carbonate, guanidine hydrochloride, aminoguanidine, aminoguanidine carbonate, aminoguanidine hydrochloride, biguanide, biguanide carbonate, biguanide hydrochloride, sulfamic acid salt of guanidine, or the like. When the guanidines are hydrochloride, pH of the polishing composition may be lowered. In this case, for increasing pH, it is preferable to use another alkaline substance together. The other alkaline substance is not limited as long as it does not adversely affect the compositions of the present invention, but an example thereof may include an alkaline substance such as sodium hydroxide, potassium hydroxide, sodium carbonate or potassium carbonate. The alkaline substance for adjusting pH is added so that pH of the polishing composition of the present invention is finally in a range of 10.2 to 12.

Since PRTR law is not applied to the above guanidines, the polishing composition in consideration of an environment can be provided.

In the present invention, a single alkaline substance may be used, or a combination of two or more alkaline substances may be used. An amount of the alkaline substance contained in the first and second polishing compositions of the present invention is, for example, in the polishing of the silicon wafer, preferably in a range of 0.15% by weight to 2.5% by weight at a use point. When the amount is less than 0.15% by weight, a polishing speed of a silicon wafer is low and therefore, such polishing composition is not practical. When the amount exceeds 2.5% by weight, a rough pattern tends to be easily generated as if the polishing surface is corroded.

(3) Water

In the present invention, water is used as a medium. It is preferable to use the water in which impurities are reduced as much as possible. For example, deionized water in which impurities ions are removed by an ion exchange resin may be used. Further, the water in which suspended materials are removed by passing the deionized water through a filter may be used, or distilled water may be used. It should be noted that in the present specification, there is a case where the water in which the impurities are reduced as much as possible is simply called “water” or “pure water”, and “water” or “pure water” means the water in which the above impurities are reduced as much as possible, unless noted otherwise.

(4) Chelating Agent

The compound of the present invention comprises a chelating agent as an optional component. The chelating agent may be selected from ethylene diamine tetraacetic acid, diethylenetriamine pentaacetic acid, nitrilotriacetic acid, N-hydroxyethylethylene diaminetriacetic acid, or hydroxyethyliminodiacetic acid. The present invention may use one of the above compounds alone, or a combination of two or more of the above compounds. An amount of the chelating agent contained in the polishing composition is, for example, in a case of polishing the silicon wafer, preferably in a range of 10 ppm to 1000 ppm at a use point of the polishing.

<Preparation of Polishing Composition>

The polishing composition of the present invention may be generally made by mixing each of the above components with water in a desired content and by dispersing them in the water. For example, in a case of using cerium oxide powder in the first polishing composition, the cerium oxide powder and the alkaline substance are mixed with water so as to give desired contents of the cerium oxide powder and the alkaline substance. In a case of using colloidal ceria, a desired concentration of the colloidal ceria may be prepared from cerium oxide powder and water, or in a case of purchasing colloidal ceria, it may be diluted with water to produce a desired concentration, if necessary. Thereafter, an alkaline substance may be added to the colloidal ceria. In a case of using colloidal silica in the first polishing composition, the same process may be adopted.

The above example is just one example and the mixing order of the colloidal ceria or the colloidal silica and the alkaline substance is arbitrarily made. For example, in the present polishing composition, any one of dispersion of each component other than the alkaline substance and dissolution of the alkaline substance may be carried out prior to the other, or both of them may be carried out at the same time. Alternatively, a desired content of the colloidal ceria or the colloidal silica and a desired content of the alkaline polishing composition may be prepared separately and then they may be mixed.

In a case of the second polishing composition in the present invention, the above alkaline substance may be mixed with water in a desired content and dissolved.

In a case where the composition of the present invention comprises a chelating agent, the chelating agent (which may be not dissolved or dissolved in water) may be dissolved in a desired content at any process of the above respective steps.

A method of dispersing or dissolving the above components into water is adopted arbitrarily. For example, the above components may be dispersed using the stirring by a blade type stirrer.

The polishing composition of the present invention may be supplied in a diluted state as used at an actual polishing process, but may be prepared as a concentrate solution in a relatively high concentration (hereinafter, simply referred to also as concentrate solution) for the supplying. This concentrate solution may be stored or transported in a concentrate solution state and diluted at an actual polishing process for use. It is preferable that the polishing composition of the present invention is, from a viewpoint of handling the polishing composition, manufactured in the form of the concentrate solution, transported and diluted at an actual polishing process.

A preferred concentration range of each aforementioned component is described as the one at an actual polishing process (use point of the polishing). In a case of a concentrate solution, the polishing composition has necessarily each component of a high concentration A preferred concentration of each component in the form of the concentrate solution, on a basis of a total weight of the polishing composition, the cerium oxide is in a range of 0.01% by weight to 10% by weight, the silicon oxide is in a range of 0.1% by weight to 20% by weight, the alkaline substance is in a range of 1% by weight to 25% by weight and the chelating agent is in a range of 0.04% to 4% by weight.

It is preferable that each of the first and second polishing compositions of the present invention has pH of 10.2 to 12.0. The polishing of the silicon wafer can be efficiently carried out within this range. It should be noted that in a case where pH of the polishing composition immediately after being prepared is out of a range of 10.2 to 12.0, an alkaline substance (for example, sodium hydroxide, potassium hydroxide, sodium carbonate or potassium carbonate) or an acid substance (for example, hydrochloric acid, sulfuric acid or nitric acid) may be added for adjusting pH. The amount of the alkaline substance added is determined so that pH is in a range of 10.2 to 12.0.

Next, a polishing method of a silicon wafer using the polishing composition of the present invention will be explained.

A wafer which is capable of being polished by the present invention is preferably a silicon wafer, such as a single crystal silicon wafer or a polycrystalline silicon wafer and the like. In the following explanation, an example of the silicon wafer will be explained.

The first polishing method of the present invention comprises a process of polishing a silicon wafer with supplying colloidal ceria comprising a cerium oxide and water or colloidal silica comprising a silicon oxide and water, and a polishing composition for a silicon wafer comprising an alkaline substance and water. Particularly, the alkaline substance is guanidines.

In the polishing method according to the present invention, firstly, the colloidal ceria or the colloidal silica comprising the cerium oxide or the silicon oxide in a desired concentration, and the alkaline polishing composition comprising the alkaline substance and water are prepared in the procedure explained in the section of the preparation method for the above polishing composition. In a case of preparing each of the colloidal ceria or the colloidal silica and the alkaline polishing composition as the concentrate solution with a high concentration, the concentrate solution is diluted with water to obtain a desired concentration. The dilution may be carried out by a known mixing or dilution method such as a stirring. Further, the chelating agent may be added if necessary. A content of the cerium oxide or the silicon oxide, a content of the alkaline substance and a content of the chelating agent are as above explained as the use point of the polishing.

Next, the polishing composition is used to polish a silicon wafer. A known method is applicable to the polishing procedure of the present invention. For example, a silicon wafer held by holding means may be in close contact with a rotational board attached with a polishing cloth, which is rotated under flow of liquid of a polishing composition for the polishing, and thus carrying out the polishing. In regard to conditions such as a flow amount of the polishing liquid and a rotational speed of the rotational board, a conventional condition range may be used depending on the condition of the polishing.

It is preferable that in the polishing composition of the present invention, each component is in advance mixed at a predetermined concentration as an polishing liquid, which then, is supplied to a polished object such as a silicon wafer.

Next, the second polishing method of the present invention will be explained.

A second polishing method of the present invention comprises polishing a silicon wafer including a steps of removing an oxidized layer of a silicon wafer surface by polishing the silicon wafer surface with colloidal ceria comprising cerium oxide and water, and subsequently polishing a silicon wafer with an alkaline polishing composition comprising an alkaline substance and water. In this method, the alkaline substance comprises guanidines.

In this method, firstly, the colloidal ceria comprising the cerium oxide in a desired concentration, and the alkaline polishing composition comprising the alkaline substance and water are prepared. The colloidal ceria can be prepared in a desired concentration from cerium oxide powder and water, or, in a case of preparing the colloidal ceria as the concentrate solution with a high concentration, the colloidal ceria can be prepared by diluting the concentrate solution with water so as to give a desired concentration of the colloidal ceria. The dilution may be carried out by a known mixing or diluting method such as a stirring. A content of the cerium oxide powder in the colloidal ceria is preferably in a range of 2.5 ppm to 1000 ppm in a use point of the polishing. The alkaline polishing composition can be prepared according to the procedure explained in the section of the preparation method of the above polishing composition.

The polishing compositions described above are used as a polishing agent to carry out the polishing by a two-step procedure comprising removing an oxidized layer (natural oxidized layer) on the silicon wafer surface and polishing a silicon wafer. In a case of using the colloidal ceria as the polishing agent, the reason for adopting the two-step method wherein includes the polishing step of the silicon wafer with the alkaline polishing composition is that the colloidal ceria can remove the natural oxidized layer, but can not polish the silicon wafer and therefore, it is necessary to carry out the polishing with the alkaline polishing composition. The removal step of the natural oxidized layer and the polishing step of the silicon wafer may be carried out of as a series of continuous processes comprising separated processes or as separated processes which are not continuous.

The colloidal ceria comprising a minute amount of the cerium oxide and water is used to polish the silicon wafer. The polishing step of using the colloidal ceria comprising a minute amount of the cerium oxide is suitable, particularly for removing the natural oxidized layer formed on the silicon wafer.

After removing the oxidized layer, the polishing of the silicon wafer is carried out by the second polishing composition of the present invention.

A known method is applicable to the polishing procedure in both of a step of removing the oxidized layer and a step of polishing the silicon wafer with the alkaline polishing composition in the second polishing method. For example, a silicon wafer held by holding means may be in close contact with a rotational board attached with a polishing cloth, which is rotated under flow of liquid of a polishing composition for the polishing, and thus carrying out the polishing. In regard to conditions such as a flow amount of the polishing liquid and a rotational speed of the rotational board, a conventional condition range may be used depending on the condition of the polishing.

It should be noted that the removal of the oxidized layer on the silicon wafer may be achieved not only by use of the colloidal ceria, but also by use of the colloidal silica comprising a large number of silicon oxides.

It is preferable that in the polishing composition of the present invention, each component is in advance mixed at a predetermined concentration as an polishing liquid, which then, is supplied to a polished object such as a silicon wafer.

Next, the polishing composition kit of the present invention will be explained.

The polishing composition kit of the present invention comprises colloidal ceria or colloidal silica and an alkaline polishing composition comprising an alkaline substance and water.

The polishing composition kit of the present invention may further comprise a chelating agent.

It is preferable that in the polishing composition kit of the present invention, the colloidal ceria or the colloidal silica and the alkaline polishing composition are respectively contained in different vessels. In addition, the chelating agent may be added to one or both of the colloidal ceria or the colloidal silica and the alkaline polishing composition.

It should be appreciated for persons skilled in the art that the above form of the polishing composition kit of the present invention is one example, and the polishing composition kit of the present invention may be modified variously. For example, the colloidal ceria or the colloidal silica may be contained in a vessel at a state of being in advance mixed with water, or the cerium oxide powder or the silicon oxide powder and the water may be contained in a vessel as separated packages. Further, the alkaline substance of the alkaline polishing composition may be contained in a vessel at a state of being in advance mixed with water, or the alkaline substance and the water may be contained in a vessel as separated packages. The chelating agent may be in advance mixed with another component and may be contained in a different vessel from the other component. That is, the respective components (each material and medium) of the polishing composition kit in the present invention may be contained respectively in separate vessels or may be contained in a single vessel in a state where a part of the respective components is in advance mixed.

In the present invention, in a case where a plurality of the alkaline substances or the chelating agents are included in the polishing composition, they may be contained in a single vessel or respectively in different vessels.

The kit of the present invention may include additional elements such as a mixing vessel and a stirrer for mixing and stirring the respective components, and an instruction for use (not limited thereto), if necessary, in addition to the respective components for the above polishing composition.

The polishing composition kit of the present invention may be packed, stored and transported in a diluted state at an actual polishing process, but may be may be packed as separated components for a concentrate solution of the polishing composition, stored and transported. In a case of the concentrate solution, for example, a high concentration of each of the colloidal ceria or the colloidal silica, the alkaline substance and the chelating agent may be packaged, stored and transported in a desired form as a kit. The concentrate components may be mixed and diluted so as to obtain a predetermined concentration immediately before the polishing.

### EXAMPLES

Hereinafter, Examples of the present invention will be described. In the following examples, the numeral value is parts by weight unless noted otherwise. The following Examples illustrate the present invention and the present invention is not limited to these Examples.

One head of holding a P++ type silicon wafer (100) of 6 inches was pressed on a rotating press platen, on which a urethane pad (SUBA600 made by Nittahass Co) was installed, to apply the pressure thereon and the head was also rotated. Further, each polishing liquid described in the following Table 1 was supplied to carry out the polishing. A weight of the wafer was measured before and after the polishing to calculate a polishing speed from a reduction of the weight. In addition, the smoothness of the polishing surface was measured by a surface roughness measuring device (Zygo New View 5022).

<Polishing Condition>
Pressure: 300 gr/cm²

Press platen rotational number: 120 rpm

Polishing liquid supply speed: 200 ml/min

Polishing liquid temperature: about 30° C.

Pad temperature at an initial stage of polishing: about 35° C.

Polishing time: 20 min

### Examples 1 to 3 and Comparative Examples 1 to 3

The polishing composition was prepared by mixing the components shown in Table 1 below. The above polishing condition was used to polish the Examples 1 to 3 and the comparative examples 1 to 3 shown in Table 1 and the polishing speed and the surface roughness were measured. The result is also shown in the Table 1.

[Table 1]

TABLE 1

| | Ex 1 | Ex 2 | Ex 3 | CE 1 | CE 2 | CE 3 |
|---|---|---|---|---|---|---|
| Colloidal | | | 0.005 | | 0.01 | 0.02 |
| ceria | | | | | | |
| Colloidal | 2 | 1 | | 7.5 | | |
| silica | | | | | | |
| Guanidine | 2.5 | 2.5 | 2.5 | | | |
| carbonate | | | | | | |
| 3.6% | 2 | 2 | 2 | | | |
| hydrochloric | | | | | | |
| acid^{a)} | | | | | | |
| TMAH^{b)} | | | | 1 | | |
| Piperazine | | | | | 20 | 20 |
| EA^{c)} | | | | | 10 | 10 |
| Water | 1000 | 1000 | 1000 | 1000 | 1000 | 1000 |
| Polishing | 0.58 | 0.68 | 0.64 | 0.80 | 0.68 | 0.74 |
| speed | | | | | | |
| (um/min) | | | | | | |
| Surface | 0.49 | 0.61 | 0.66 | 0.98 | 0.90 | 0.90 |
| roughness | | | | | | |
| Ra (nm) | | | | | | |

Ex: Example
CE: Comparative example
^{a)}3.6% of hydrochloric acid was added for adjusting pH.
^{b)}TMAH: tetramethylammonium hydroxide
^{c)}EA: N-(2-aminoethyl)ethanol

As shown in Table 1, as compared to the conventional alkaline substance, the surface roughness becomes smaller when guanidine carbonate is used.

### Examples 4 to 7

Examples of a two-step polishing of a silicon wafer using colloidal ceria and an alkaline polishing composition are shown.

<Preparation of Polishing Liquid>

Polishing Liquid A

Components shown in Table 2 below were mixed to prepare the polishing liquid A (colloidal ceria polishing agent).

[Table 2]

TABLE 2

| DIW ^{a)} | Colloidal ceria ^{b)} |
|---|---|
| 1000 | 0.05 |

^{a)} DIW: deionized water
^{b)} colloidal ceria: solution comprising cerium oxide of 10% by weight

Polishing Liquid B

Components shown in Table 3 below were mixed to prepare the polishing liquid B (alkaline polishing composition).

[Table 3]

TABLE 3

| | | 3.6% of hydrochloric |
|---|---|---|
| DIW ^{a)} | Guanidine carbonate | acid |
| 1000 | 2.5 | 2 |

^{a)} DIW: deionized water

The above polishing condition was used to polish according to Examples 4 to 7 shown in Table 4 for measuring the polishing speed.

[Table 4]

TABLE 4

| | |
|---|---|
| Example 4 | The polishing liquid A was used to polish for |
| | 30 sec and immediately after that, the polishing |
| | liquid A was replaced by the polishing liquid |
| | B to polish for 20 min in total. |
| Example 5 | The polishing liquid A was used to polish for |
| | 1 min and immediately after that, the polishing |
| | liquid A was replaced by the polishing liquid |
| | B to polish for 20 min in total. |
| Example 6 | The polishing liquid A was used to polish for |
| | 6 min and immediately after that, the polishing |
| | liquid A was replaced by the polishing liquid |
| | B to polish for 20 min in total. |
| Example 7 | The polishing liquid A was used to polish for |
| | 20 min (the polishing by the polishing liquid |
| | B was not carried out). |

Result

The polishing speed (micron/min) of each of Examples 4 to 7 was as shown in Table 5 below.

[Table 5]

TABLE 5

| | |
|---|---|
| Example 4 | 0.64 |
| Example 5 | 0.63 |
| Example 6 | 0.50 |
| Example 7 | 0.050 |

The above result shows that the polishing liquid A acts only on the oxidized layer and does not act on the silicon polishing. In addition, the above result shows that the polishing liquid B polishes the silicon after removing the oxidized layer.

### INDUSTRIAL APPLICABILITY

The present invention is applicable to a field of polishing a semiconductor wafer.

1. An polishing composition for a silicon wafer comprising:
a metal oxide, an alkaline substance and water, wherein the alkaline substance is guanidines.

2. An polishing composition for a silicon wafer comprising:
an alkaline substance and water, wherein the alkaline substance is guanidines.

3. An polishing composition for a silicon wafer according to claim 1, further comprising a chelating agent.

4. An polishing composition for a silicon wafer according to claim 1, wherein the guanidines are selected from guanidine, guanidine carbonate, guanidine hydrochloride, aminoguanidine, aminoguanidine carbonate, aminoguanidine hydrochloride, biguanide, biguanide carbonate, biguanide hydrochloride, or sulfamic acid salt of guanidine and in a case where the guanidines are hydrochlorides, another alkaline substance is also used for increasing pH.

5. An polishing composition for a silicon wafer according to claim 3, wherein the chelating agent is selected from ethylene diamine tetraacetic acid, diethylenetriamine pentaacetic acid, nitrilotriacetic acid, N-hydroxyethylethylene diaminetriacetic acid, or hydroxyethyliminodiacetic acid.

6. An polishing composition for a silicon wafer according to claim 1, wherein the polishing composition is diluted before polishing the silicon wafer.

7. An polishing composition for a silicon wafer according to claim 1, wherein the polishing composition has pH of 10.2 to 12.0.

8. An polishing composition for a silicon wafer according to claim 1, wherein the metal oxide is selected from cerium oxide or silicon oxide.

9. A polishing method of a silicon wafer comprising:
polishing a silicon wafer with supplying a polishing composition which comprises colloidal ceria comprising a cerium oxide and water or colloidal silica comprising a silicon oxide and water, and an alkaline polishing composition comprising an alkaline substance and water, wherein the alkaline substance is guanidines.

10. A polishing method of a silicon wafer comprising:
polishing a silicon wafer comprising steps of removing an oxidized layer on a silicon wafer surface by polishing the silicon wafer surface with colloidal ceria comprising cerium oxide and water, and subsequently polishing a silicon wafer with an alkaline polishing composition comprising an alkaline substance and water, wherein the alkaline substance is guanidines.

11. A polishing method of a silicon wafer according to claim 9, wherein the polishing composition further comprises a chelating agent.

12. A polishing method of a silicon wafer according to claim 9, wherein the guanidines is selected from guanidine, guanidine carbonate, guanidine hydrochloride, aminoguanidine, aminoguanidine carbonate, aminoguanidine hydrochloride, biguanide, biguanide carbonate, biguanide hydrochloride, or sulfamic acid salt of the guanidine, and in a case where the guanidines are hydrochlorides, another alkaline substance is also used for increasing pH.

13. A polishing method of a silicon wafer according to claim 11, wherein the chelating agent is selected from ethylene diamine tetraacetic acid, diethylenetriamine pentaacetic acid, nitrilotriacetic acid, N-hydroxyethylethylene diaminetriacetic acid, or hydroxyethyliminodiacetic acid.

14. An polishing composition kit for a silicon wafer comprising:
a dispersion comprising a cerium oxide or a silicon oxide and water; and
an alkaline polishing composition comprising an alkaline substance, which is guanidines, and water.

15. An polishing composition kit for a silicon wafer according to claim 14, wherein the dispersion and/or the alkaline polishing composition further comprise a chelating agent.

16. An polishing composition for a silicon wafer according to claim 2, further comprising a chelating agent.

17. An polishing composition for a silicon wafer according to claim 2, wherein the guanidines are selected from guanidine, guanidine carbonate, guanidine hydrochloride, aminoguanidine, aminoguanidine carbonate, aminoguanidine hydrochloride, biguanide, biguanide carbonate, biguanide hydrochloride, or sulfamic acid salt of guanidine and in a case where the guanidines are hydrochlorides, another alkaline substance is also used for increasing pH.

18. An polishing composition for a silicon wafer according to claim 2, wherein the polishing composition is diluted before polishing the silicon wafer.

19. An polishing composition for a silicon wafer according to claim 2, wherein the polishing composition has pH of 10.2 to 12.0.

20. A polishing method of a silicon wafer according to claim 10, wherein the polishing composition further comprises a chelating agent.

21. A polishing method of a silicon wafer according to claim 10, wherein the guanidines is selected from guanidine, guanidine carbonate, guanidine hydrochloride, aminoguanidine, aminoguanidine carbonate, aminoguanidine hydrochloride, biguanide, biguanide carbonate, biguanide hydrochloride, or sulfamic acid salt of the guanidine, and in a case where the guanidines are hydrochlorides, another alkaline substance is also used for increasing pH.
